(19) United States
(12) Patent Application Publication
(10) Pub. No.: US 2024/0240979 A1
(43) Pub. Date: Jul. 18, 2024

(54) AIRTIGHT HOUSING, FLUID METERING DEVICE, AND METHOD FOR PRODUCING A HOUSING

(71) Applicant: Diehl Metering GmbH, Ansbach (DE)

(72) Inventors: Axel Schmidt, Ansbach (DE); Andreas Seifert, Unterschwaningen (DE); Claus Zellner, Ansbach (DE); Thomas Sturm, Sachsen (DE); Patrick Hünenberger, Ansbach (DE)

(21) Appl. No.: 18/524,704

(22) Filed: Nov. 30, 2023

(30) Foreign Application Priority Data
Jan. 18, 2023 (DE) 10 2023 101 203.7

(51) Int. Cl. G01F 15/14

(52) U.S. Cl. CPC G01F 15/14

(57) ABSTRACT

An airtight housing, in particular electronics housing, is suitable for use in different ambient pressure conditions. The housing has housing walls of a plastics material. At least one of the housing walls has a pressure compensating device that seals a cutout in the housing wall in an airtight manner. The pressure compensating device has an elastic, flat compensating element located on top of the cutout.

### CROSS-REFERENCE TO RELATED APPLICATION

This application claims the priority, under 35 U.S.C. § 119, of German Patent Application DE 10 2023 101 203.7, filed Jan. 18, 2023; the prior application is herewith incorporated by reference in its entirety.

### FIELD AND BACKGROUND OF THE INVENTION

The invention relates to an airtight housing, in particular an electronics housing, for use in different ambient pressure conditions, having housing walls consisting of a plastics material. The invention further relates to a fluid metering device and a method for producing such an airtight housing.

In many applications, in particular for electronic components, there exists the desire for an optimal protection of the components to be received in a housing which goes beyond simply protecting against dust and liquid. This is the case, for example, for fluid metering devices, in particular water meters and/or gas meters and/or heat meters, or the communication modules, for example radio modules, of such fluid metering devices, which are designed to be used in very different and sometimes adverse environmental conditions and thus are designed to be robust and functionally reliable. For such applications, the full casting-in of electronic components or other components to be protected, in order to form the housing which encloses the components, has already been proposed in the prior art. On the one hand, it is known to use fully curing, shape-forming casting masses so that, for example in the case of electronic components, a so-called molded electronic module can be produced. A further method provides for the use of a shape-forming frame with the object to carry out a gel casting of the components to be arranged inside the frame (a so-called framed module).

While these solutions provide an effective protection, in particular also an airtight seal of the components, they also have drawbacks. For example, recycling is exceptionally difficult in the case of electronic components. Moreover, a large amount of material is required for the casting mass, whereby the total weight of the housing also increases with the components received therein.

Thus it has been proposed to use airtight housings which are made of plastics and which comprise housing walls, the components, in particular the electronic components, being able to be arranged in the inner cavity thereof. However, in fluid metering devices, for example, such housings are intended to be used in very different environmental conditions and thus also very different ambient pressure conditions. Different pressure conditions can prevail inside the airtight housing and outside the airtight housing, for example, due to temperature fluctuations, weather effects, and the like. Different geographical altitudes during production and at the subsequent place of use can also lead to differential pressures relative to the environment. This pressure difference can have a negative effect on the housing since the housing walls are subjected to stress by the difference in pressure and thus can be damaged, in particular, over their service life and this can lead to an opening through which air, moisture, dirt and liquids can enter.

Relevant solutions which use diaphragms which are impenetrable to dust and water but which permit an air exchange, so that a pressure compensation is present, are known in the prior art. However, such diaphragms cannot always be used when an air tightness of the housing is required, for example, in order to prevent the penetration of moist air, and the like.

### SUMMARY OF THE INVENTION

It is accordingly an object of the invention to provide a housing and a method which overcome a variety of disadvantages of the heretofore-known devices and methods of this general type and which reduces the level of stress applied to housing parts in different environmental conditions and thus improves the protection of components, in particular electronic components, received in the housing in an airtight manner.

With the above and other objects in view there is provided, in accordance with the invention, an airtight housing for use in different ambient pressure conditions, the housing comprising:
housing walls consisting of a plastics material;
at least one of said housing walls being formed with a cutout and having a pressure compensating device configured to seal said cutout in said housing wall in an airtight manner, with said pressure compensating device having an elastic, flat compensating element disposed to cover said cutout.

In other words, to achieve the objects of the invention, there is provided according to the invention that at least one of the housing walls has a pressure compensating device sealing a cutout in the housing wall in an airtight manner, with a resilient, flat compensating element located on top of the cutout.

According to the invention, therefore, an elastic and airtight compensating element is proposed as part of the airtight housing. In the region of a cutout of the, in particular thermoplastic, dimensionally stable housing wall, the elastic compensating element thus separates the housing interior, i.e., an inner cavity of the housing, from the environment. When there is a difference in pressure between the housing interior and the environment, this results in the compensating element being able to be deflected in a corresponding direction, wherein this deflection can take place both inwardly and outwardly. This deflection of the air compensating element leads to an increase or a reduction in the air volume enclosed in the airtight housing. Due to the relationship between the pressure and the volume inside a sealed interior, this leads to a pressure compensation of the interior of the airtight housing relative to the environment.

In this manner, the pressure compensating element permits a reduction in the level of stress applied to the housing parts of the airtight housing, in particular the housing walls, due to pressure differences between the housing interior and the environment, as can be caused for example by temperature fluctuations, weather effects and different geographical altitudes. In this case, the air tightness of the housing continues to be ensured so that there is no airflow, no ingress of moist air and thus no additional entry of moisture into the airtight housing.

The housing can be, in particular, an airtight electronics housing which thus receives electronic components as the components to be protected. For example, a printed circuit board bearing at least one electronic component, for example a chip or the like, can be arranged inside the housing and protected in an improved and durable manner.

The compensating element can be configured, for example, as a flexible and elastic, or resilient, compensating diaphragm which is airtight.

Particularly advantageously, the compensating element can consist of an elastomeric material, in particular a thermoplastic elastomer (TPE). The pressure compensating device, which may also be referred to as a pressure-compensating means, can be particularly advantageously configured in one piece so that it can consist as a whole of an elastomeric material, in particular a thermoplastic elastomer. Thus an embodiment can be provided in which both the housing and the pressure compensating means consist of plastics, wherein the housing can consist, in particular, of a thermoplastic dimensionally stable or hard plastics, and the pressure compensating means and thus the pressure compensating element can consist of a soft plastics having the desired resilient properties, in particular TPE.

The pressure compensating means can have a connecting portion for the mounting in the cutout and for the sealing. In particular, an at least one-sided overlap with the housing wall is provided for the connecting portion on the edge of the cutout where the airtight mounting or connection is produced. In the case of the one-piece pressure compensating means, this can comprise, for example, the compensating element which is located flat on top of the cutout, while outwardly the connecting portion adjoins the edge of the cutout.

In this context, it is particularly advantageous if the connecting portion of the one-piece pressure compensating means is held by a material connection on the edge of the cutout on the housing wall side. A material connection already provides the desired air tightness and thus is particularly advantageous.

In this context, a general and particularly advantageous embodiment provides that at least the housing wall, which comprises the pressure compensating means, and the pressure compensating means are manufactured by two-component injection molding. In this manner, the pressure compensating means are produced in one piece and attached by a material connection to the housing wall on the edge of the cutout in a robust and airtight manner. In a first step, at least the housing wall which comprises the pressure compensating means, optionally also the entire housing, can be injection molded from a thermosetting plastic as the first component, after which in a second step the pressure compensating means is added with a soft plastics, for example a thermoplastic elastomer, and the cutout in the housing wall is covered by the resilient pressure compensating means. The resulting material connection ensures the air tightness of the entire housing. Alternative but less preferred exemplary embodiments can also provide that the housing wall with the cutout and the pressure compensating means are manufactured separately and joined together in a subsequent step, for example by material connections such as adhesive bonding or other fastening means which seal in an airtight manner.

At this point it should also be mentioned that, in particular in addition to the material fastening of the pressure compensating means on the housing wall, a fastening by a positive connection is also conceivable in principle, for example by the connecting portion encompassing the edge of the cutout. A particularly advantageous embodiment providing robust and reliable air tightness and fastening is produced when the material and positive connection is manufactured in a two-component injection molding method, in particular by the connecting portion of the one-piece pressure compensating means encompassing the edge of the cutout.

The cutout can advantageously be round, in particular circular. This has proved to be an optimal solution regarding the forces which occur in the case of a convexity or concavity due to a difference in pressure, and the distribution of these forces. Moreover, due to the symmetry, in particular with a circular cutout, this results in a lower resistance to deformation for the pressure compensation.

The housing according to the invention can be particularly advantageously used with fluid metering devices, for example water meters and/or gas meters and/or heat meters, for the electronics used therein, in particular at least parts of a corresponding control device and/or for communication modules, in particular radio modules. Specifically regarding fluid metering devices, there is the desire for air tightness for ideal protection of the electronics, but also for use under very different environmental conditions which the airtight housing in the embodiment according to the invention can withstand in an improved manner while the air tightness is maintained.

The invention thus also relates to a fluid metering device, in particular a water meter and/or a gas meter, comprising a counter and a control device which is arranged at least partially in a housing according to the invention. All of the embodiments relative to the housing according to the invention can be transferred equally to the fluid metering device according to the invention by which the aforementioned advantages can be achieved. For example, the fluid metering device can be an ultrasonic measuring device, in which electronic components which have to be particularly protected are present as part of the control device.

The invention finally also relates to a method for producing a housing according to the invention which is characterized in that at least the housing wall, which comprises the pressure compensating means, is manufactured by two-component injection molding. As already set forth, this preferably results directly in a material connection which robustly maintains the air tightness. A thermoplastic material can be used as the component for the housing wall and a thermoplastic elastomer can be used as the component for the pressure compensating means. In an expedient development, as already mentioned, a positive connection between the housing wall and the pressure compensating means can also be produced by the two-component injection molding, in particular by the housing wall being encompassed by means of the pressure compensating means in a connecting portion. The embodiments relative to the airtight housing according to the invention naturally also continue to apply relative to the method.

Other features which are considered as characteristic for the invention are set forth in the appended claims.

Although the invention is illustrated and described herein as embodied in an airtight housing, a fluid metering device, and a method for producing a housing, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 shows a schematic perspective view of a housing according to the invention;

FIG. 2 shows a partial cross-sectional view of the housing, taken along the line II-II shown in FIG. 1;

FIG. 3 shows the cross-sectional view of FIG. 2 with the presence of a first changed ambient pressure;

FIG. 4 shows the cross-sectional view of FIG. 2 with the presence of a second changed ambient pressure;

FIG. 5 shows a schematic, complete cross-sectional view of the housing, taken along the line V-V in FIG. 1; and

FIG. 6 shows a schematic sketch of a fluid metering device according to the invention.

### DETAILED DESCRIPTION OF THE INVENTION

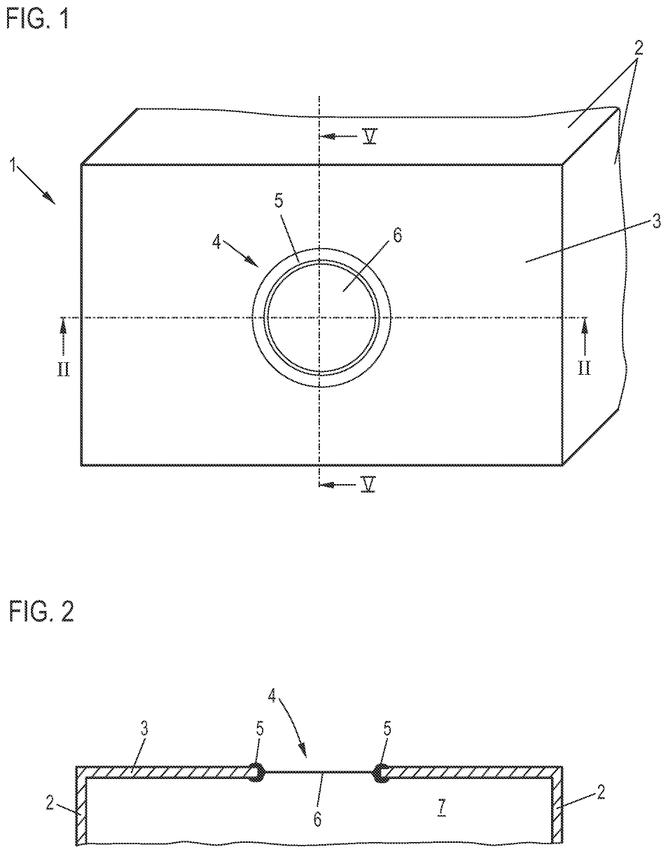

Referring now to the figures of the drawing in detail and first, in particular, to FIG. 1 thereof, there is shown an exterior view of an airtight housing 1 according to the invention. In the present case the housing 1 has a cuboidal shape which is formed, in particular, by non-resilient or rigid housing walls 2, 3 defining an internal cavity. The housing walls 2, 3 consist of a thermoplastic material. A circular cutout in the housing wall 3 is sealed by a pressure compensating device 4 which is held by a material connection and a positive (i.e., form-lock) connection. The one-piece pressure compensating device 4 comprises a connecting portion 5 for mounting in the cutout and a flat, resilient, central compensating element 6 covering the cutout.

The housing 1 has been produced in a two-component injection molding process, wherein the housing walls 2, 3 have been initially formed from the thermoplastic material as the first component, after which in a further step the pressure compensating device 4 has been formed from a thermoplastic elastomer as the second component.

The partial cross-sectional view along the line II-II in FIG. 1, which is shown in FIG. 2, shows the state of the pressure compensating device 4 and, in particular, the compensating element 6 in the case of an ambient pressure which corresponds to the pressure in the interior of the housing 1 when the housing 1 is sealed in an airtight manner. The compensating element 6 is thus located in a basic position which continues the housing wall 3 in a straight line through the cutout and in which no pressure compensation is required since there is no difference in pressure between the environment and the housing interior 7. The illustration in FIG. 2 also shows how the connecting portion 5 of the one-piece pressure compensating device 4 encompasses the housing wall 3 on the edge of the cutout, in order to bring about a positive connection in addition to a material connection between the thermoplastic material and the thermoplastic elastomer.

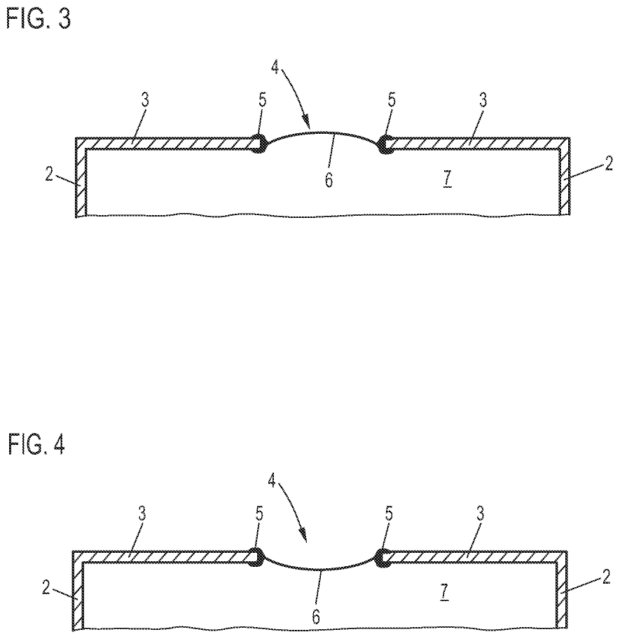

If an ambient pressure which is lower than the pressure in the housing interior 7 now prevails, the resilient compensating element is deformed and bulges outwardly so that the volume for the air in the housing interior 7 increases and the pressure difference is compensated as shown in FIG. 3.

FIG. 4 shows the reverse case in which an overpressure has occurred in the environment relative to the housing interior 7 and has led to a deformation of the resilient compensating element 6 inwardly, thus with an inward bulging.

In this manner, the resilient compensating element 6 of the pressure compensating device 4 ensures a pressure compensation between the housing interior 7 and the environment without negatively affecting the air tightness.

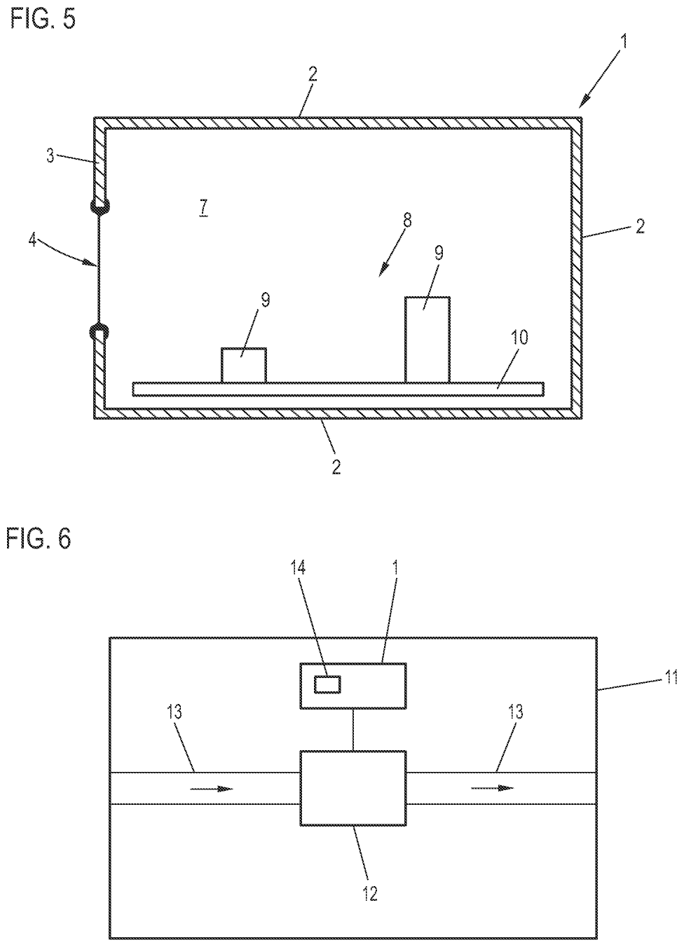

FIG. 5 shows in a full cross-sectional view along the line V-V of FIG. 1 that the airtight housing 1 in the present case is an electronics housing in which electronic components 8, in the present case electronic structural parts 9, are arranged in a protected manner on a printed circuit board 10.

FIG. 6 finally shows schematically a fluid metering device 11 according to the invention, for example a water meter. A counter 12 is connected to corresponding line portions 13 for the fluid. The operation of the fluid metering device 11 is controlled by a control device 14 which is at least partially arranged in an airtight housing 1 according to the present invention. The counter 12 may for example, be an ultrasonic counter.

The following is a summary list of reference numerals and the corresponding structure used in the above description of the invention:
1 Airtight housing
2 Housing wall
3 Housing wall
4 Pressure compensating device
5 Connecting portion
6 Compensating element
7 Housing interior
8 Electronic component
9 Electronic structural part
10 Printed circuit board
11 Fluid metering device
12 Counter
13 Line portion
14 Control device

1. An airtight housing for use in different ambient pressure conditions, the housing comprising:
housing walls consisting of a plastics material;
at least one of said housing walls being formed with a cutout and having a pressure compensating device configured to seal said cutout in said housing wall in an airtight manner, with said pressure compensating device having an elastic, flat compensating element disposed to cover said cutout.

2. The airtight housing according to claim 1, wherein said compensating element consists of an elastomeric material.

3. The airtight housing according to claim 2, wherein said elastomeric material is a thermoplastic elastomer.

4. The airtight housing according to claim 1, wherein said pressure compensating device has a connecting portion configured for mounting in said cutout and for sealing said pressure compensating device against said at least one wall.

5. The airtight housing according to claim 4, wherein said pressure compensating device is a one-piece device, and aid connecting portion of said one-piece pressure compensating device is held by a material connection on an edge of said cutout on a housing wall side thereof.

6. The airtight housing according to claim 5, wherein said connecting portion forms a positive connection in addition to the material connection.

7. The airtight housing according to claim 6, wherein said connecting portion embraces said housing wall on the edge of said cutout.

8. The airtight housing according to claim 1, wherein said at least one housing wall, which has said pressure compensating device, and said pressure compensating device are manufactured by two-component injection molding.

9. The airtight housing according to claim 1, wherein said cutout is a round cutout.

10. The airtight housing according to claim 9, wherein said cutout is a circular cutout.

11. The airtight housing according to claim 1, further comprising a printed circuit board bearing at least one electronic component arranged in a housing void inside the housing.

12. The airtight housing according to claim 1 configured as an electronics housing.

13. A fluid metering device, comprising:
a housing according to claim 1;
a counter and a control device at least partially arranged in said housing.

14. A method for producing a housing according to claim 1, the method which comprises forming at least the housing wall, which has the pressure compensating device, by a two-component injection molding process.

15. The method according to claim 14, which comprises using a thermoplastic material component to form the housing wall and using a thermoplastic elastomer component to form the pressure compensating device.
